(19) United States
(12) Patent Application Publication
(10) Pub. No.: US 2025/0295005 A1
(43) Pub. Date: Sep. 18, 2025

(54) DISPLAY DEVICE AND METHOD OF FABRICATING THE DISPLAY DEVICE

(71) Applicant: Samsung Display Co., LTD., Yongin-si (KR)

(72) Inventors: Young Suk LEE, Yongin-si (KR); Yong Jun PARK, Yongin-si (KR)

(21) Appl. No.: 18/932,848

(22) Filed: Oct. 31, 2024

(30) Foreign Application Priority Data
Mar. 14, 2024 (KR) 10-2024-0036028

(51) Int. Cl. H10K 59/80; H10K 59/12; H10K 59/122; H10K 59/131

(52) U.S. Cl. CPC H10K 59/873; H10K 59/1201; H10K 59/122; H10K 59/131

(57) ABSTRACT

A display device includes a substrate including an emission area and a non-emission area; a first light emitting element positioned on the emission area of the substrate; a pixel defining layer positioned on the non-emission area of the substrate and defining a first opening; a bank structure positioned on the pixel defining layer, defining a second opening, and including a groove; and a first encapsulation layer positioned on the first light emitting element and the bank structure. The bank structure includes: a first bank layer including a first side surface facing the emission area and a second side surface opposing the first side surface; and a second bank layer positioned on the first bank layer and including a first tip protruding toward the emission area and a second tip protruding toward the groove. The first encapsulation layer entirely covers the first tip and the second tip.

This application claims priority to Korean Patent Application No. 10-2024-0036028, filed on Mar. 14, 2024, and all the benefits accruing therefrom under 35 U.S.C. § 119, the content of which in its entirety is herein incorporated by reference.

### BACKGROUND

### 1. Technical Field

The present disclosure relates to a display device and a method of fabricating the display device.

### 2. Description of the Related Art

As the information society develops, the demand for display devices for displaying images has increased and diversified. For example, display devices have been applied to various electronic devices such as, for example, smartphones, digital cameras, laptop computers, navigation devices, and smart televisions. The display devices may be flat panel display devices such as, for example, liquid crystal display devices, field emission display devices, or organic light emitting display devices. Among such flat panel display devices, a light emitting display device may display an image without a backlight unit providing light to a display panel because each of pixels of the display panel includes light emitting elements that may emit light by themselves.

With the development of various electronic devices, the demand for high-aperture ratio and high-resolution display devices has increased. Since some high-aperture ratio and high-resolution display devices may require a high degree of integration of pixels, a display device corresponding to the high degree of integration of the pixels and a method of fabricating the display device are desired.

### SUMMARY

Aspects of the present disclosure provide a display device in which a reliability defect caused by moisture permeation is solved, and a method of fabricating the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

In an embodiment of the disclosure, a display device includes a substrate including an emission area and a non-emission area; a first light emitting element positioned on the emission area of the substrate; a pixel defining layer positioned on the non-emission area of the substrate and defining a first opening; a bank structure positioned on the pixel defining layer, defining a second opening, and including a groove; and a first encapsulation layer positioned on the first light emitting element and the bank structure, wherein the bank structure includes: a first bank layer including a first side surface facing the emission area and a second side surface opposing the first side surface; and a second bank layer positioned on the first bank layer and including a first tip protruding toward the emission area more than the first side surface and a second tip protruding toward the groove more than the second side surface, and the first encapsulation layer entirely covers the first tip and the second tip.

In an embodiment, the display device may further include a second light emitting element spaced apart from the first light emitting element with the pixel defining layer and the bank structure interposed between the second light emitting element spaced apart and the first light emitting element, wherein the first light emitting element and the second light emitting element are in contact with the first bank layer.

In an embodiment, the first light emitting element and the second light emitting element may be electrically connected to each other through the first bank layer.

In an embodiment, the first bank layer may include aluminum, and the second bank layer includes titanium.

In an embodiment, in a plan view, the second opening may entirely surround the first opening.

In an embodiment, the first light emitting element may include an anode electrode, a light emitting layer, and a cathode electrode, and the light emitting layer and the cathode electrode may be in contact with the first side surface.

In an embodiment, the display device may further include an organic pattern positioned on the second bank layer, including a same material as the light emitting layer, and spaced apart from the light emitting layer; and an electrode pattern positioned on the organic pattern, including a same material as the cathode electrode, and spaced apart from the cathode electrode, wherein the organic pattern and the electrode pattern overlap the first tip and the second tip.

In an embodiment, the organic pattern and the electrode pattern may be positioned such that the organic pattern and the electrode pattern surround the first opening, and the first encapsulation layer entirely covers the organic pattern and the electrode pattern.

In an embodiment, the display device may further include a residual pattern positioned between the anode electrode and the pixel defining layer in a direction perpendicular to the substrate, wherein the residual pattern overlaps the first tip.

In an embodiment, the residual pattern may be in contact with the light emitting layer.

In an embodiment, the first bank layer may include a first portion in contact with the first light emitting element; a second portion in contact with the second light emitting element; and a third portion overlapping the groove, the first portion, the second portion, and the third portion are integrally formed, and the third portion is positioned between the first portion and the second portion.

In an embodiment, the third portion may be spaced apart from the first encapsulation layer with a space interposed between the third portion and the first encapsulation layer in a direction perpendicular to the substrate.

In an embodiment, the display device may further include a second encapsulation layer positioned on the first encapsulation layer, wherein the third portion may be in contact with the second encapsulation layer.

In an embodiment, the second bank layer may include a first sub-portion positioned on the first portion of the first bank layer and a second sub-portion positioned on the second portion of the first bank layer, and the first sub-portion and the second sub-portion are spaced apart from each other in a direction parallel to the substrate.

In an embodiment, the first encapsulation layer may include a first inorganic layer entirely covering the first sub-portion and a second inorganic layer entirely covering the second sub-portion, and the first inorganic layer and the second inorganic layer are spaced apart from each other in the direction parallel to the substrate.

In an embodiment, the first bank layer may include a first portion in contact with the first light emitting element; a second portion spaced apart from the first portion and not in contact with the first light emitting element; and a third portion overlapping the groove, the first portion, the second portion, and the third portion are integrally formed, and the third portion is positioned between the first portion and the second portion.

In an embodiment, the second bank layer may include a first sub-portion positioned on the first portion and a second sub-portion positioned on the second portion, and the first sub-portion and the second sub-portion are spaced apart from each other in a direction parallel to the substrate.

In an embodiment, the display device may further include an organic pattern and an electrode pattern positioned on the first sub-portion of the second bank layer; and an organic residual pattern and an electrode residual pattern positioned on the third portion of the first bank layer, wherein the organic pattern and the organic residual pattern are spaced apart from each other, and the electrode pattern and the electrode residual pattern are spaced apart from each other.

In an embodiment, the first encapsulation layer entirely may cover the electrode pattern and the electrode residual pattern.

In an embodiment of the disclosure, a method of fabricating a display device includes forming a substrate including an emission area and a non-emission area, forming an anode electrode and a sacrificial layer on the emission area of the substrate, and then forming a pixel defining layer and a bank structure on the sacrificial layer, the bank structure including a first bank layer and a second bank layer; exposing the anode electrode by removing the pixel defining layer and the bank structure positioned in a portion overlapping the emission area, and forming a groove by removing a portion of the bank structure positioned in a portion overlapping the non-emission area; forming the second bank layer including a first tip and a second tip by removing portions of the bank structure, the first tip protruding toward the emission area more than a first side surface of the first bank layer and the second tip protruding toward the groove more than a second side surface of the first bank layer; and forming a light emitting element by forming a light emitting layer and a cathode electrode on the anode electrode and the bank structure, and forming an encapsulation layer entirely covering the first tip and the second tip.

In an embodiment of the disclosure, an electronic device includes a display device comprising: a substrate comprising an emission area and a non-emission area; a first light emitting element positioned on the emission area of the substrate; a pixel defining layer positioned on the non-emission area of the substrate and defining a first opening; a bank structure positioned on the pixel defining layer, defining a second opening, and comprising a groove; and a first encapsulation layer positioned on the first light emitting element and the bank structure, wherein: the bank structure comprises: a first bank layer comprising a first side surface facing the emission area and a second side surface opposing the first side surface; and a second bank layer positioned on the first bank layer and comprising a first tip protruding toward the emission area more than the first side surface and a second tip protruding toward the groove more than the second side surface, and the first encapsulation layer entirely covers the first tip and the second tip.

Detailed contents of other embodiments are described in a detailed description and are illustrated in the drawings.

In accordance with one or more embodiments of the present disclosure, a display device and a method of fabricating the display device are provided which solve a reliability defect occurring due to permeation of moisture and oxygen caused in a fabricating process of the display device.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a schematic cross-sectional view of the display device of FIG. 1;

FIG. 3 is a plan view illustrating an arrangement of emission areas in a display area of FIG. 2;

FIG. 4 is a cross-sectional view of a display layer taken along line X1-X1′ of FIG. 3;

FIG. 5 is an enlarged cross-sectional view of a display element layer and a thin film encapsulation layer overlapping a first emission area in FIG. 4;

FIG. 6 is an enlarged cross-sectional view of a display element layer and a thin film encapsulation layer overlapping a non-emission area positioned between a first emission area and a second emission area in FIG. 4;

FIGS. 7 to 18 are schematic cross-sectional views illustrating a method of fabricating the display element layer and the thin film encapsulation layer in FIG. 4;

FIG. 19 is a schematic cross-sectional view of a display area taken along line X1-X1′ of FIG. 3 according to another embodiment; and

FIG. 20 is an enlarged cross-sectional view of a display element layer and a thin film encapsulation layer overlapping a non-emission area positioned between a first emission area and a second emission area in FIG. 19.

### DETAILED DESCRIPTION

The invention now will be described more fully hereinafter with reference to the accompanying drawings, in which various embodiments are illustrated. Aspects supported by the present disclosure may, however, be embodied in many different forms, and should not be construed as limited to the embodiments set forth herein. Rather, the example embodiments are provided such that this disclosure will be thorough and complete, and will fully convey the scope of example aspects of the present disclosure to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third,” and the like may be used herein to describe various elements, components, regions, layers and/or sections, these elements, components, regions, layers and/or sections should not be limited by these terms. These terms are used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The terms “about” or “approximately” can mean within one or more standard deviations, or within +30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings.

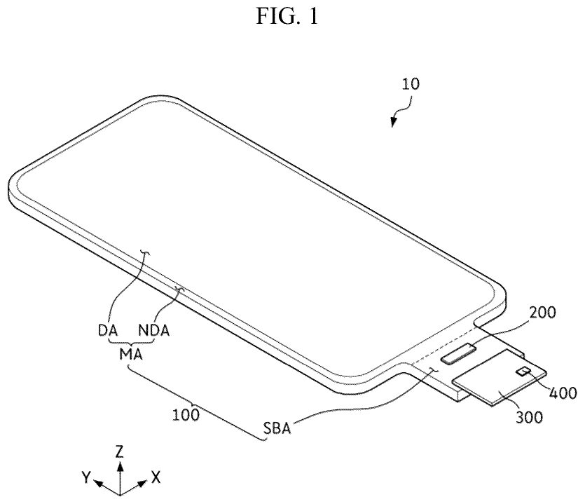

FIG. 1 is a perspective view illustrating a display device according to an embodiment.

Referring to FIG. 1, a display device 10 displays a moving image or a still image. The display device 10 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, which provide display screens, may be included in the display device 10.

In FIG. 1, a first direction (X-axis direction), a second direction (Y-axis direction), and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) refers to a transverse direction in the drawings, the second direction (Y-axis direction) refers to a longitudinal direction in the drawings, and the third direction (Z-axis direction) refers to an upward and downward direction (i.e., a thickness direction) in the drawings. In the following specification, unless otherwise specified, the term “direction” may refer to both directions toward both sides extending along the direction. In some aspects, when both “directions” extending to both sides are to be distinguished from each other, one side will be referred to as “one side in the direction” and the other side will be referred to as “the other side in the direction”. In FIG. 1, a direction to which an arrow indicating a direction is directed will be referred to as one side, and a direction opposite to such a direction will be referred to as the other side.

Hereinafter, for convenience of explanation, in referring to surfaces of respective members constituting the display device 1, one surface facing one side in a direction in which an image is displayed, that is, the third direction (Z-axis direction) will be referred to as an upper surface, and a surface opposite to the one surface will be referred to as the other surface. However, embodiments of the present disclosure are not limited thereto, and the one surface and the other surface of the member may be referred to as a front surface and a rear surface, respectively, or be referred to as a first surface and a second surface, respectively. In some aspects, in describing relative positions of the respective members of the display device 10, one side in the third direction (Z-axis direction) may be referred to as an upper portion and the other side in the third direction (Z-axis direction) may be referred to as a lower portion.

A shape of the display device 10 may be variously changed. For example, the display device 10 may have a shape such as, for example, a rectangular shape with a width greater than a length, a rectangular shape with a length greater than a width, a square shape, a rectangular shape with rounded corners (vertices), other polygonal shapes, or a circular shape.

The display device 10 may include a display panel 100, a display driver 200, a circuit board 300, and a touch driver 400.

The display panel 100 may include a main area MA and a sub-area SBA. The main area MA may include a display area DA including pixels displaying an image and a non-display area NDA disposed around the display area DA. The main area MA and the sub-area SBA may include a flexible material that may be bent, folded, and rolled.

The display area DA is an area where a screen may be displayed, and the non-display area NDA is an area where the screen is not displayed. The display area DA may also be referred to as an active area, and the non-display area NDA may also be referred to as a non-active area. The display area DA may occupy substantially the center of the display device 10. The non-display area NDA may be an area outside the display area DA. The non-display area NDA may be defined as an edge area of the main area MA of the display panel 100. The non-display area NDA may include lines supplying signals to the display area DA and lines connecting the display driver 200 and the display area DA to each other. The sub-area SBA may be an area extending from one side of the main area MA. In

an example in which the sub-area SBA is bent, the sub-area SBA may overlap the main area MA in the thickness direction (e.g., the third direction (Z-axis direction)). The sub-area SBA may include the display driver 200 and display pads connected to the circuit board 300. In another embodiment, the sub-area SBA may be omitted, and the display driver 200 and the display pads may be positioned in the non-display area NDA.

The display driver 200 may output signals and voltages for driving the display panel 100. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be disposed in the sub-area SBA, and may overlap the main area MA in the thickness direction by bending of the sub-area SBA. As another example, the display driver 200 may be mounted on the circuit board 300.

The circuit board 300 may be attached onto the display pads of the display panel 100 using an anisotropic conductive film (ACF). The circuit board 300 may be electrically connected to the display pads. The circuit board 300 may be a flexible printed circuit board, a printed circuit board, or a flexible film such as, for example, a chip on film.

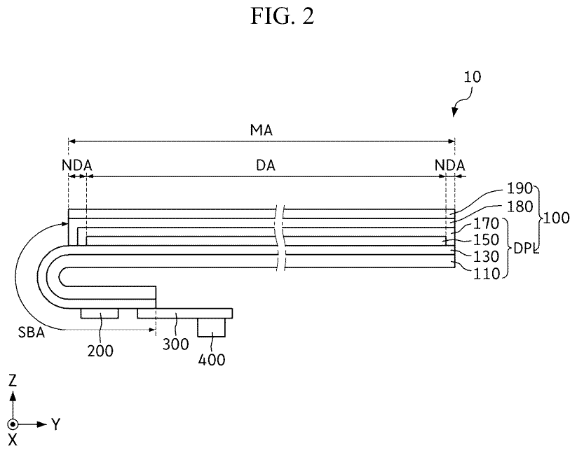

The touch driver 400 may be mounted on the circuit board 300. The touch driver 400 may be connected to a touch sensor layer 180 (see FIG. 2) of the display panel 100.

FIG. 2 is a schematic cross-sectional view of the display device of FIG. 1.

Referring to FIG. 2, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate that may be bent, folded, and rolled. For example, the substrate 110 may include a polymer resin such as, for example, polyimide (PI), but is not limited thereto. In another embodiment, the substrate 110 may include a glass material or a metal material.

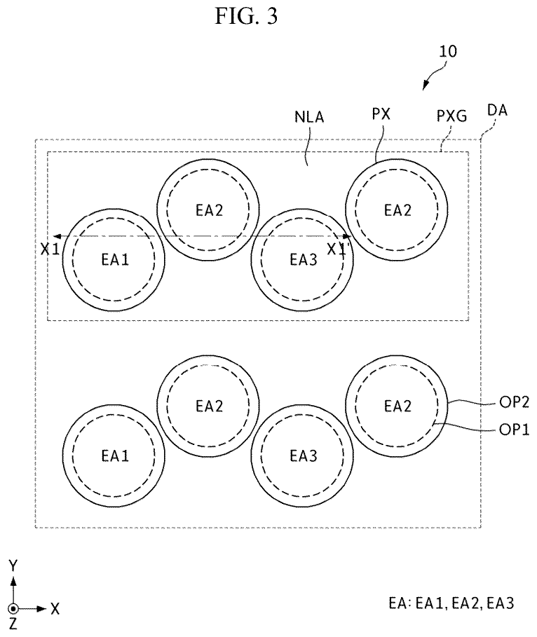

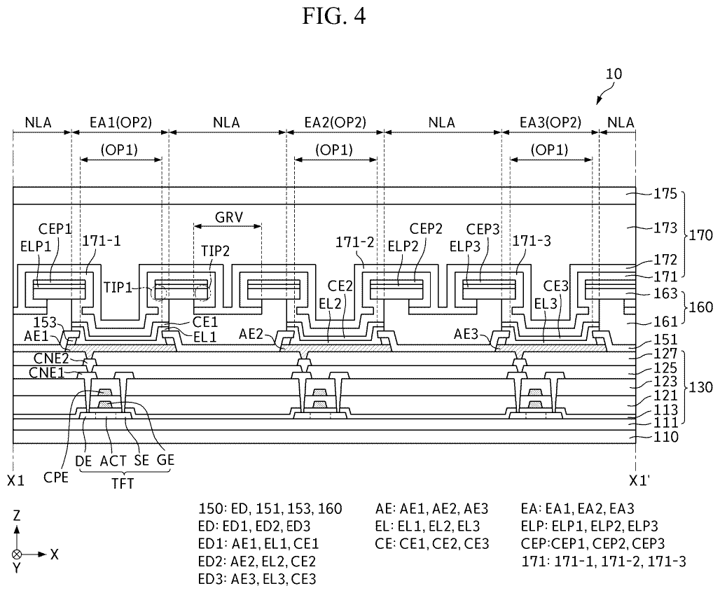

The thin film transistor layer 130 may be disposed on the substrate 110. The thin film transistor layer 130 may be positioned in portions overlapping the display area DA, the non-display area NDA, and the sub-area SBA. The thin film transistor layer 130 may include a plurality of thin film transistors TFT (see FIG. 4) constituting a pixel PX (see FIG. 3).

The display element layer 150 may be disposed on the thin film transistor layer 130. The display element layer 150 may be positioned in a portion overlapping the display area DA. The display element layer 150 may include at least one of an organic light emitting diode (LED) including an organic light emitting layer, a quantum dot LED including a quantum dot light emitting layer, an inorganic LED including an inorganic semiconductor, and a micro LED, but is not limited thereto.

The thin film encapsulation layer 170 may be positioned on the display element layer 150. The thin film encapsulation layer 170 may be positioned in portions overlapping the display area DA and the non-display area NDA. The thin film encapsulation layer 170 may cover an upper surface and side surfaces of the display element layer 150, and may protect the display element layer 150 from external oxygen and moisture. The thin film encapsulation layer 170 may include at least one inorganic film and at least one organic film for encapsulating the display element layer 150.

The touch sensor layer 180 may be disposed on the thin film encapsulation layer 170. The touch sensor layer 180 may be positioned in portions overlapping the display area DA and the non-display area NDA. The touch sensor layer 180 may sense a user's touch in a mutual capacitance manner or a self-capacitance manner. The color filter layer 190 may be disposed on the touch sensor layer 180. The color filter layer 190 may be positioned in portions overlapping the display area DA and the non-display area NDA. The color filter layer 190 may absorb some of light introduced from the outside of the display device 10 to reduce reflected light by external light. Accordingly, for example, the color filter layer 190 may prevent distortion of colors due to external light reflection.

Since the color filter layer 190 is directly disposed on the touch sensor layer 180, the display device 10 may be implemented without a separate substrate for the color filter layer 190. Accordingly, for example, a thickness of the display device 10 may be relatively small. The color filter layer 190 may also be omitted according to embodiments.

As illustrated in FIG. 2, a portion of the display layer DPL overlapping the sub-area SBA may be bent. In an example in which a portion of the display layer DPL is bent, the display driver 200, the circuit board 300, and the touch driver 400 may overlap the main area MA in the third direction (Z-axis direction).

FIG. 3 is a plan view illustrating an arrangement of emission areas in a display area of FIG. 2.

Referring to FIG. 3, the display area DA according to an embodiment may include an emission area EA and a non-emission area NLA.

The emission area EA may include first emission areas EA1, second emission areas EA2, and third emission areas EA3 that emit light of different colors. The first to third emission areas EA1, EA2, and EA3 may emit red, green, or blue light, respectively, and colors of the light emitted from the first to third emission areas EA1, EA2, and EA3 may be different from each other depending on types of light emitting elements ED (see FIG. 4) to be described later. As an example, the first emission area EA1 may emit the red light, the second emission area EA2 may emit the green light, and the third emission area EA3 may emit the blue light, but embodiments of the present disclosure are not limited thereto. It has been illustrated in FIG. 3 that sizes or shapes of the first to third emission areas EA1, EA2, and EA3 are the same as each other, but embodiments of the present disclosure are not limited thereto. That is, sizes and shapes of the first to third emission areas EA1, EA2, and EA3 may be freely adjusted according to target (e.g., required) characteristics.

The emission area EA may be defined by a first opening OP1 and a second opening OP2. In a plan view, the second opening OP2 may completely surround the first opening OP1, and may be completely surrounded by the non-emission area NLA.

In some embodiments, at least one first emission area EA1, at least one second emission area EA2, and at least one third emission area EA3 disposed adjacent to each other may constitute one pixel group PXG. The pixel group PXG may be a minimum unit emitting white light. It has been illustrated in FIG. 3 that one first emission area EA1, two second emission areas EA2, and one third emission area EA3 constitute the pixel group PXG, but embodiments of the present disclosure are not limited thereto. Types and/or the numbers of first to third emission areas EA1, EA2, and EA3 constituting the pixel group PXG may be variously changed according to embodiments.

The non-emission area NEA may be positioned such that the non-emission area NEA surrounds the emission area EA. The non-emission area NLA may block each light emitted from a plurality of first to third emission areas EA1, EA2, and EA3. The non-emission area NLA may assist in preventing each light emitted from the plurality of first to third emission areas EA1, EA2, and EA3 from being mixed with each other.

FIG. 4 is a cross-sectional view of a display layer taken along line X1-X1′ of FIG. 3.

FIG. 4 is a partial cross-sectional view of the display device 10 overlapping the display area DA, and illustrates cross sections of the substrate 110, the thin film transistor layer 130, the display element layer 150, and the thin film encapsulation layer 170. The substrate 110 has already been described, and a description thereof is thus omitted.

Referring to FIG. 4, the thin film transistor layer 130 may be positioned on the substrate 110. The thin film transistor layer 130 may include a first buffer layer 111, thin film transistors TFT, a gate insulating layer 113, a first interlayer insulating layer 121, capacitor electrodes CPE, a second interlayer insulating layer 123, first connection electrodes CNE1, a first via layer 125, second connection electrodes CNE2, and a second via layer 127.

The first buffer layer 111 may be disposed on the substrate 110. The first buffer layer 111 may include an inorganic film capable of preventing permeation of air or moisture. For example, the first buffer layer 111 may include a plurality of inorganic films that are alternately stacked.

The thin film transistor TFT may be disposed on the first buffer layer 111, and may constitute a pixel circuit connected to each of a plurality of pixels. As an example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be disposed on the first buffer layer 111. The active layer ACT may overlap the gate electrode GE in the third direction (Z-axis direction), and may be insulated from the gate electrode GE by the gate insulating layer 113. The source electrode SE and the drain electrode DE may be formed by making a material of the active layer ACT in portions of the active layer ACT conductors.

The gate electrode GE may be disposed on the gate insulating layer 113. The gate electrode GE may overlap the active layer ACT with the gate insulating layer 113 interposed between the gate electrode GE and the active layer ACT.

The gate insulating layer 113 may be disposed on the active layer ACT. For example, the gate insulating layer 113 may cover the active layer ACT and the first buffer layer 111, and may insulate the active layer ACT and the gate electrode GE from each other. The gate insulating layer 113 may include contact holes through which the first connection electrodes CNE1 penetrate.

The first interlayer insulating layer 121 may cover the gate electrode GE and the gate insulating layer 113. The first interlayer insulating layer 121 may include contact holes through which the first connection electrodes CNE1 penetrate. The contact holes of the first interlayer insulating layer 121 may be connected to the contact holes of the gate insulating layer 113 and contact holes of the second interlayer insulating layer 123.

The capacitor electrodes CPE may be disposed on the first interlayer insulating layer 121. The capacitor electrode CPE may overlap the gate electrode GE in the third direction (Z-axis direction). The capacitor electrode CPE and the gate electrode GE may form capacitance.

The second interlayer insulating layer 123 may cover the capacitor electrodes CPE and the first interlayer insulating layer 121. The second interlayer insulating layer 123 may include contact holes through which the first connection electrodes CNE1 penetrate. The contact holes of the second interlayer insulating layer 123 may be connected to the contact holes of the first interlayer insulating layer 121 and the contact holes of the gate insulating layer 113.

The first connection electrodes CNE1 may be disposed on the second interlayer insulating layer 123. The first connection electrode CNE1 may electrically connect the drain electrode DE of the thin film transistor TFT and the second connection electrode CNE2 to each other. The first connection electrode CNE1 may be inserted into the contact holes formed in the first interlayer insulating layer 121, the second interlayer insulating layer 123, and the gate insulating layer 113 to be in contact with the drain electrode DE of the thin film transistor TFT.

The first via layer 125 may cover the first connection electrodes CNE1 and the second interlayer insulating layer 123. The first via layer 125 may planarize an underlying structure. The first via layer 125 may include contact holes through which the second connection electrodes CNE2 penetrate.

The second connection electrodes CNE2 may be disposed on the first via layer 125. The second connection electrodes CNE2 may be inserted into the contact holes formed in the first via layer 125 to be in contact with the first connection electrodes CNE1. The second connection electrode CNE2 may electrically connect the first connection electrode CNE1 and an anode electrode AE to each other.

The second via layer 127 may cover the second connection electrodes CNE2 and the first via layer 125. The second via layer 127 may include contact holes through which the anode electrodes AE penetrate.

The display element layer 150 according to an embodiment may be disposed on the thin film transistor layer 130. The display element layer 150 may include a light emitting element ED, a pixel defining layer 151, residual patterns 153, and a bank structure 160.

The light emitting element ED according to an embodiment may include a first light emitting element ED1 disposed in the first emission area EA1, a second light emitting element ED2 disposed in the second emission area EA2, and a third light emitting element ED3 disposed in the third emission area EA3.

The first to third light emitting elements ED1, ED2, and ED3 may emit light of different colors depending on materials of a light emitting layer EL. For example, the first light emitting element ED1 may emit the red light, the second light emitting element ED2 may emit the green light, and the third light emitting element ED4 may emit the blue light.

The light emitting element ED may include an anode electrode AE, a light emitting layer EL, and a cathode electrode CE. As an example, the first light emitting element ED1 may include a first anode electrode AE1, a first light emitting layer EL1, and a first cathode electrode CE1, the second light emitting element ED2 may include a second anode electrode AE2, a second light emitting layer EL2, and a second cathode electrode CE2, and the third light emitting element ED3 may include a third anode electrode AE3, a third light emitting layer EL3, and a third cathode electrode CE3.

The anode electrode AE according to an embodiment may be disposed on the second via layer 127. The anode electrode AE may be electrically connected to the drain electrode DE of the thin film transistor TFT through the first connection electrode CNE1 and the second connection electrode CNE2.

The anode electrode AE may include the first anode electrode AE1 positioned in the first emission area EA1, the second anode electrode AE2 positioned in the second emission area EA2, and the third anode electrode AE3 positioned in the third emission area EA3. The first to third anode electrodes AE1, AE2, and AE3 may be disposed to be spaced apart from each other on the second via layer 127.

The pixel defining layer 151 according to an embodiment may be positioned on the second via layer 127 and the anode electrode AE. The pixel defining layer 151 may define a first opening OP1. The pixel defining layer 151 may expose the anode electrode AE at a portion of the anode electrode AE overlapping the first opening OP1, and the light emitting layer EL may be directly disposed on the anode electrode AE at the portion of the anode electrode AE overlapping the first opening OP1.

The pixel defining layer 151 may include an inorganic insulating material. As an example, the pixel defining layer 151 may include any one of aluminum oxide, titanium oxide, tantalum oxide, hafnium oxide, zinc oxide, silicon oxide, silicon nitride, and silicon oxynitride.

The bank structure 160 according to an embodiment may be positioned on the pixel defining layer 151. The bank structure 160 may define a second opening OP2. The bank structure 160 may include a first bank layer 161 and a second bank layer 163 that include different metal materials and structures and play different roles.

The bank structure 160 may include a first tip TIP1 positioned in a portion overlapping the emission area EA. In general, in a high-resolution display device, an interval between a plurality of light emitting elements ED neighboring to each other may be narrow. Accordingly, for example, due to the narrow interval, it may be difficult to form a plurality of light emitting elements ED included in the high-resolution display device using a mask in a fabricating process. In accordance with one or more embodiments of the present disclosure, the bank structure 160 of the display device 10 includes the first tips TIP1, which supports forming the plurality of light emitting elements ED overlapping the first to third emission areas EA1, EA2, and EA3 without using a mask in the fabricating process.

The bank structure 160 according to an embodiment may include a groove GRV positioned in a portion overlapping the non-emission area NLA. The groove GRV may be formed by etching a portion of the bank structure 160 in the fabricating process of the display device 10. The fabricating process will be described later.

The bank structure 160 according to an embodiment may include a second tip TIP2 positioned in a portion overlapping the groove GRV. The second tip TIP2 may be formed in the same process as a process of forming the groove GRV. Detailed contents thereof will be described later.

The light emitting layer EL according to an embodiment may be disposed on the anode electrode AE. The light emitting layer EL may be an organic light emitting layer formed of an organic material, and may be formed on the anode electrode AE through a deposition process. In an example in which the thin film transistor TFT applies a predetermined voltage to the anode electrode AE and the cathode electrode CE receives a common voltage or a cathode voltage, holes and electrons may move to the light emitting layer EL through a hole transporting layer and an electron transporting layer, respectively, and may be combined with each other in the light emitting layer EL to emit light.

The light emitting layer EL may include the first light emitting layer EL1, the second light emitting layer EL2, and the third light emitting layer EL3 respectively disposed in the first to third emission areas EA1, EA2, and EA3. As an example, the first light emitting layer EL1 may be a light emitting layer emitting the red light, the second light emitting layer EL2 may be a light emitting layer emitting the green light, and the third light emitting layer EL3 may be a light emitting layer emitting the blue light, but embodiments of the present disclosure are not limited thereto.

The residual pattern 153 according to an embodiment may be positioned between the anode electrode AE and the pixel defining layer 151 in the third direction (Z-axis direction). Detailed contents thereof will be described later.

The cathode electrode CE according to an embodiment may be disposed on the light emitting layer EL. The cathode electrode CE may include a transparent conductive material to emit the light generated from the light emitting layer EL. The cathode electrode CE may receive a common voltage or a low potential voltage. In an example in which the anode electrode AE receives a voltage corresponding to a data voltage and the cathode electrode CE receives the low potential voltage, a potential difference is formed between the anode electrode AE and the cathode electrode CE, such that the light emitting layer EL may emit the light.

The cathode electrode CE may include the first cathode electrode CE1, the second cathode electrode CE2, and the third cathode electrode CE3. The first cathode electrode CE1 may be disposed on the first light emitting layer EL1 in the first emission area EA1, the second cathode electrode CE2 may be disposed on the second light emitting layer EL2 in the second emission area EA2, and the third cathode electrode CE3 may be disposed on the third light emitting layer EL3 in the third emission area EA3.

The first cathode electrode CE1, the second cathode electrode CE2, and the third cathode electrode CE3 may be spaced apart from each other, with the bank structure 160 interposed between the first cathode electrode CE1 and the second cathode electrode CE2 and between the second cathode electrode CE2 and the third cathode electrode CE3. The first cathode electrode CE1, the second cathode electrode CE2, and the third cathode electrode CE3 may be electrically connected to each other through the first bank layer 161 of the bank structure 160.

An organic pattern ELP according to an embodiment may be positioned on the bank structure 160. The organic pattern ELP may be disposed on the second bank layer 163 such that the organic pattern ELP surrounds the first opening OP1. The organic pattern ELP may include the same material as the light emitting layer EL.

The organic pattern ELP may include a first organic pattern ELP1, a second organic pattern ELP2, and a third organic pattern ELP3. As an example, the first organic pattern ELP1 may include the same material as the first emitting layer EL1, the second organic pattern ELP2 may include the same material as the second emitting layer EL2, and the third organic pattern ELP3 may include the same material as the third light emitting layer EL3. The organic pattern ELP may be a trace formed while a material forming the light emitting layer EL is disconnected from the light emitting layer EL rather than being connected to the light emitting layer EL in the fabricating process of the display device 10 because the bank structure 160 includes the first tip TIP1.

An electrode pattern CEP according to an embodiment may be positioned on the organic pattern ELP. The electrode pattern CEP may be disposed on the organic pattern ELP such that the electrode pattern CEP surrounds the first opening OP1. The electrode pattern CEP may include the same material as the cathode electrode CE.

The electrode pattern CEP may include a first electrode pattern CEP1, a second electrode pattern CEP2, and a third electrode pattern CEP3. As an example, the first electrode pattern CEP1 may include the same material as the first cathode electrode CE1, the second electrode pattern CEP2 may include the same material as the second cathode electrode CE2, and the third electrode pattern CEP3 may include the same material as the third cathode electrode CE3. The electrode pattern CEP may be a trace formed while a material forming the cathode electrode CE is disconnected from the cathode electrode CE rather than being connected to the cathode electrode CE in the fabricating process of the display device 10 because the bank structure 160 includes the first tip TIP1.

The thin film encapsulation layer 170 according to an embodiment may be positioned on the display element layer 150. The thin film encapsulation layer 170 may prevent oxygen or moisture from permeating into the display element layer 150, and may protect the display element layer 150 from foreign substances such as, for example, dust. The thin film encapsulation layer 170 may include a first encapsulation layer 171, a second encapsulation layer 172, a third encapsulation layer 173, and a fourth encapsulation layer 175 that are sequentially stacked. The first encapsulation layer 171, the second encapsulation layer 172, and the fourth encapsulation layer 175 may include one or more inorganic insulating materials, and the third encapsulation layer 173 may include a polymer-based organic material.

The first encapsulation layer 171 according to an embodiment may entirely cover the first tip TIP1 and the second tip TIP2 of the bank structure 160. In the display device 10 according to an embodiment, the first encapsulation layer 171 may prevent permeation of moisture and oxygen caused in the fabricating process by entirely covering the first tip TIP1 and the second tip TIP2. Accordingly, for example, the display device 10 according to an embodiment may solve a reliability defect due to the permeation of the moisture and oxygen.

The first encapsulation layer 171 according to an embodiment may include first to third inorganic layers 171-1, 171-2, and 171-3. The first to third inorganic layers 171-1, 171-2, and 171-3 may be positioned in portions overlapping the respective emission areas EA1, EA2, and EA3. As an example, the first inorganic layer 171-1 may cover the first cathode electrode CE1 and the first electrode pattern CEP1 in a portion overlapping the first emission area EA1, the second inorganic layer 171-2 may cover the second cathode electrode CE2 and the second electrode pattern CEP2 in a portion overlapping the second emission area EA2, and the third inorganic layer 171-3 may cover the third cathode electrode CE2 and the third electrode pattern CEP3 in a portion overlapping the third emission area EA3. The first to third inorganic layers 171-1, 171-2, and 171-3 may be spaced apart from each other in a portion overlapping the non-emission area NLA.

It has been illustrated in FIG. 4 that the first to third inorganic layers 171-1, 171-2, and 171-3 are formed at the same layer, but the first to third inorganic layers 171-1, 171-2, and 171-3 may be formed in different processes, respectively. As an example, the first inorganic layer 171-1 may be formed after the first cathode electrode CE1 is formed, the second inorganic layer 171-2 may be formed after the second cathode electrode CE2 is formed, and the third inorganic layer 171-3 may be formed after the third cathode electrode CE3 is formed. The fabricating process will be described later.

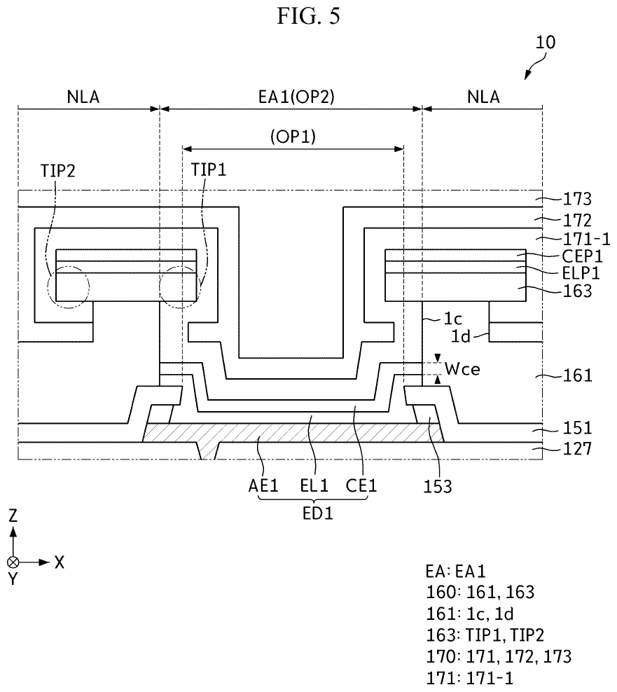

FIG. 5 is an enlarged cross-sectional view of a display element layer and a thin film encapsulation layer overlapping a first emission area in FIG. 4.

Referring to FIG. 5, the pixel defining layer 151 may be positioned on the second via layer 127 and the first anode electrode AE1. The pixel defining layer 151 may be spaced apart from the first anode electrode AE1 in the third direction (Z-axis direction) in a portion overlapping the second opening OP2, and the residual pattern 153 may be positioned in a portion where the pixel defining layer 151 and the first anode electrode AE1 are spaced apart from each other. The residual pattern 153 may be in contact with the first light emitting layer EL1, and may be positioned to overlap the first tip TIP1 in the third direction (Z-axis direction).

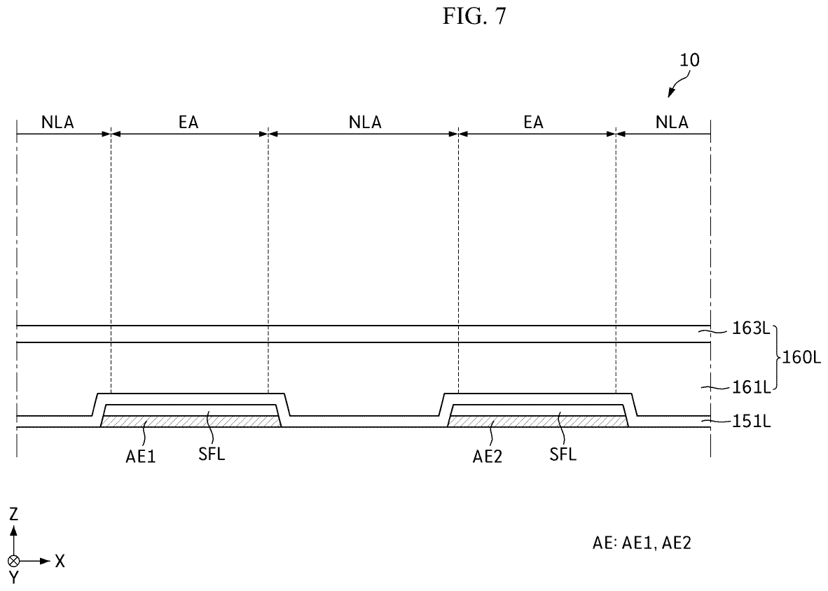

The display device 10 may include a sacrificial layer SFL (see FIG. 7) disposed between the pixel defining layer 151 and the anode electrode AE in the fabricating process. The sacrificial layer SFL may be disposed between the pixel defining layer 151 and the anode electrode AE and then partially removed by a subsequent etching process. In this case, a portion of the sacrificial layer SFL that is not removed may remain as the residual pattern 153 between the pixel defining layer 151 and the anode electrode AE1. The fabricating process will be described later.

The first bank layer 161 according to an embodiment may be positioned on the pixel defining layer 151. The first bank layer 161 may include a metal having high electrical conductivity. As an example, the first bank layer 161 may include aluminum (Al).

In some embodiments, the first bank layer 161 may include a first side surface 1c and a second side surface 1d. The first side surface 1c may be one surface facing the first opening OP1, and may be positioned to be depressed more than the pixel defining layer 151 in the first direction (X-axis direction). The second side surface 1d may be positioned in a portion overlapping the non-emission area NLA, and may be one surface opposing the first side surface 1c.

The first light emitting layer EL1 and the first cathode electrode CE1 according to an embodiment may be in contact with the first side surface 1c. In the display device 10 according to an embodiment, the greater the contact area Wce between the first cathode electrode CE1 and the first side surface 1c, the lower the electrical resistance may be. Accordingly, for example, the contact area Wce between the cathode electrode CE and the first side surface 1c of the first bank layer 161 may be adjusted according to target (e.g., required) characteristics of the display device 10.

The second bank layer 163 according to an embodiment may be positioned on the first bank layer 161. The second bank layer 163 may include a material having a lower etch rate than the first bank layer 161. As an example, the second bank layer 163 may include titanium (Ti).

The second bank layer 163 may include the first tip TIP1 protruding toward the first opening OP1 more than the side surface 161c of the first bank layer 161. Accordingly, for example, the first tip TIP1 of the second bank layer 163 and the first side surface 1c of the first bank layer 161 may form an undercut in a portion overlapping the first emission area EA1. In some aspects, the second bank layer 163 may include the second tip TIP2 protruding to one side in the first direction (X-axis direction) more than the second side surface 1d of the first bank layer 161. Accordingly, for example, the second tip TIP2 of the second bank layer 163 and the second side surface 1d of the first bank layer 161 may form an undercut in a portion overlapping the non-emission area NLA.

The first organic pattern ELP1 according to an embodiment may be positioned to overlap the first tip TIP1 and the second tip TIP2 of the second bank layer 163. In some aspects, the first electrode pattern CEP1 according to an embodiment may be positioned to overlap the first tip TIP1 and the second tip TIP2 of the second bank layer 163.

The first inorganic layer 171-1 according to an embodiment may entirely cover the first light emitting element ED1 in a portion overlapping the first opening OP1, and may entirely cover the first side surface 1c of the first bank layer 161 and the first tip TIP1 of the second bank layer 163 may in a portion overlapping the second opening OP2. In some aspects, the first inorganic layer 171-1 according to an embodiment may entirely cover the second tip TIP2 of the second bank layer 163 and may cover a portion of the second side surface 1d of the first bank layer 161, in a portion overlapping the non-emission area NLA. In some aspects, the first inorganic layer 171-1 according to an embodiment may entirely cover the first organic pattern ELP1 and the first electrode pattern CEP1.

In the display device 10 according to an embodiment, the first inorganic layer 171-1 may prevent permeation of moisture and oxygen caused in the fabricating process by entirely covering the first tip TIP1 and the second tip TIP2 of the second bank layer 163, the first organic pattern ELP1, and the first organic pattern CEP1. Accordingly, for example, the display device 10 according to an embodiment may solve a reliability defect due to the permeation of the moisture and oxygen. An overlapping description is omitted.

For convenience of explanation, the display element layer 150 and the thin film encapsulation layer 170 positioned in a portion overlapping the first emission area EA1 have been illustrated and described, but structures and characteristics of the display element layer 150 and the thin film encapsulation layer 170 positioned in portions overlapping the second emission area EA2 and the third emission area EA3 may be the same as those described herein.

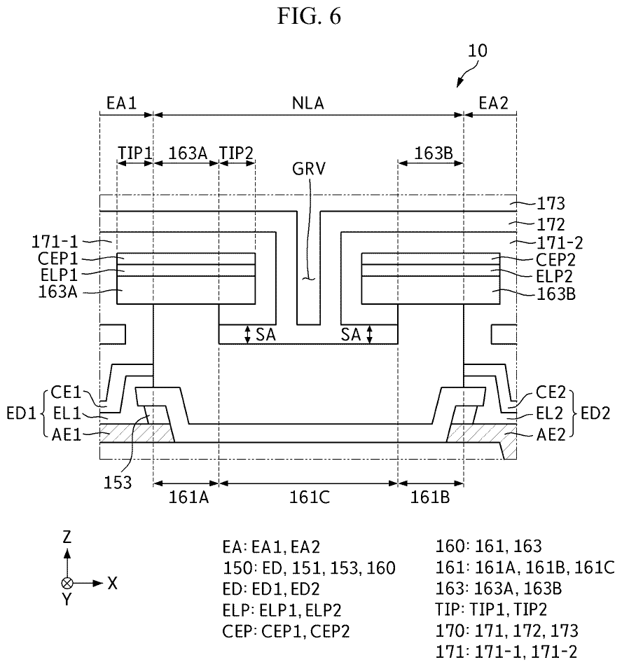

FIG. 6 is an enlarged cross-sectional view of a display element layer and a thin film encapsulation layer overlapping a non-emission area positioned between a first emission area and a second emission area in FIG. 4.

Referring to FIG. 6, the first anode electrode AE1 and the second anode electrode AE2 according to an embodiment may be spaced apart from each other with the pixel defining layer 151 interposed between the first anode electrode AE1 and the second anode electrode AE2. In some aspects, the first light emitting element ED1 and the second light emitting element ED2 may be spaced apart from each other with the pixel defining layer 151 and the bank structure 160 interposed between the first light emitting element ED1 and the second light emitting element ED2.

The bank structure 160 according to an embodiment may include the groove GRV positioned in a portion overlapping the non-emission area NLA. The groove GRV may refer to a portion where the first bank layer 161 and the second bank layer 163 are partially removed in a portion overlapping the non-emission area NLA. In other words, the groove GRV may refer a portion where the first bank layer 161 and the second bank layer 163 are partially indented in a direction toward the pixel defining layer 151. The groove GRV may be formed by performing an etching process in the fabricating process of the display device 10. A fabricating method will be described later.

The groove GRV according to an embodiment may have a bent shape according to different etch rates of the first bank layer 161 and the second bank layer 163. That is, a width of the groove GRV in the first direction (X-axis direction) may be greater between a plurality of first bank layers 161 than between a plurality of second bank layers 163.

In some embodiments, the first bank layer 161 may include a first portion 161A, a second portion 161B, and a third portion 161C. The first portion 161A may be a portion in contact with the first light emitting element ED1, the second portion 161B may be portion in contact with the second light emitting element ED2, and the third portion 161C may be a portion overlapping the groove GRV.

The third portion 161C may be positioned between the first portion 161A and the second portion 161B in the first direction (X-axis direction). In other words, the first portion 161A and the second portion 161B may be spaced apart from each other with the third portion 161C interposed between the first portion 161A and the second portion 161B. The third portion 161C may not be in contact with the light emitting element ED. The first portion 161A, the second portion 161B, and the third portion 161C may be integrally formed. That is, the first portion 161A and the second portion 161B may be extended by the third portion 161C.

In some embodiments, the second bank layer 163 may include a first sub-portion 163A and a second sub-portion 163B. The first sub-portion 163A may be a portion positioned on the first portion 161A of the first bank layer 161 and in contact with the first portion 161A. The second sub-portion 163B may be a portion positioned on the second portion 161B of the first bank layer 161 and in contact with the second portion 161B. The first sub-portion 163A and the second sub-portion 163B may be spaced apart from each other in the first direction (X-axis direction) with the groove GRV interposed between the first sub-portion 163A and the second sub-portion 163B. The first sub-portion 163A and the second sub-portion 163B may be electrically connected to each other by the first bank layer 161.

In an embodiment, the first organic pattern ELP1 and the first electrode pattern CEP1 may be positioned on the first sub-portion 163A of the second bank layer 163, and the second organic pattern ELP2 and the second electrode pattern CEP2 may be positioned on the second sub-portion 163B of the second bank layer 163. The first organic pattern ELP1 and the second organic pattern ELP2 may be spaced apart from each other with the groove GRV of the bank structure 160 interposed between the first organic pattern ELP1 and the second organic pattern ELP2, and the first electrode pattern CEP1 and the second electrode pattern CEP2 may be spaced apart from each other with the groove GRV of the bank structure 160 interposed therebetween.

The first encapsulation layer 171 according to an embodiment may be spaced apart from the first bank layer 161 in the third direction (Z-axis direction) with a space SA interposed therebetween in a portion overlapping the groove GRV of the bank structure 160.

The space SA may be formed by forming the organic pattern ELP and the electrode pattern CEP in the fabricating process of the display device 10 and then removing the organic pattern ELP and the electrode pattern CEP in a subsequent process. A fabricating method will be described later.

The first inorganic layer 171-1 and the second inorganic layer 171-2 may entirely surround the first tip TIP1 and the second tip TIP2 of the second bank layer 163. The first inorganic layer 171-1 and the second inorganic layer 171-2 may be spaced apart from each other with the groove GRV of the bank structure 160 interposed between the first inorganic layer 171-1 and the second inorganic layer 171-2. An overlapping description is omitted.

The second encapsulation layer 172 according to an embodiment may be positioned on the first encapsulation layer 171. The second encapsulation layer 172 may cover the first encapsulation layer 171 along a profile formed by the first inorganic layer 171-1 and the second inorganic layer 171-2 in a portion overlapping the non-emission area NLA. The second encapsulation layer 172 may fill the space SA formed between the first encapsulation layer 171 and the first bank layer 161.

The third encapsulation layer 173 according to an embodiment may planarize a profile formed by the second encapsulation layer 172. An overlapping description is omitted.

For convenience of explanation, the display element layer 150 and the thin film encapsulation layer 170 positioned in portions overlapping the first emission area EA1 and the second emission area EA2 have been illustrated and described, but structures and characteristics of the display element layer 150 and the thin film encapsulation layer 170 positioned in a portion overlapping the third emission area EA3 may be the same as those described herein.

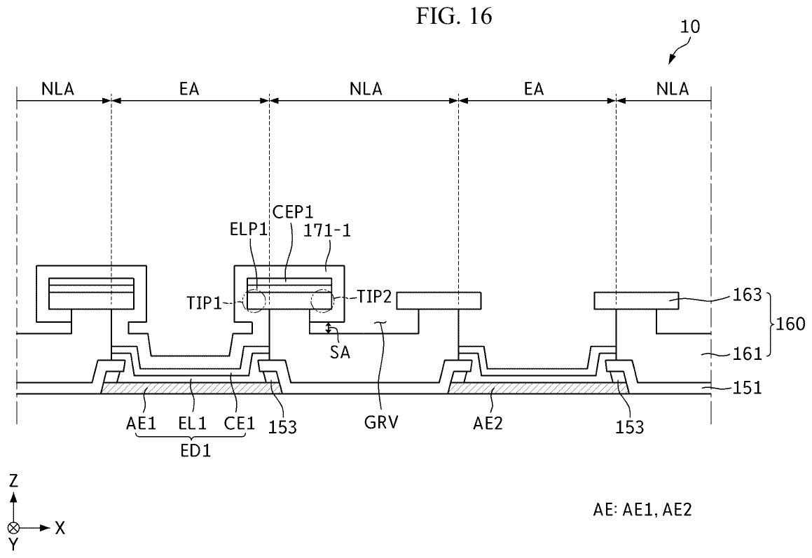

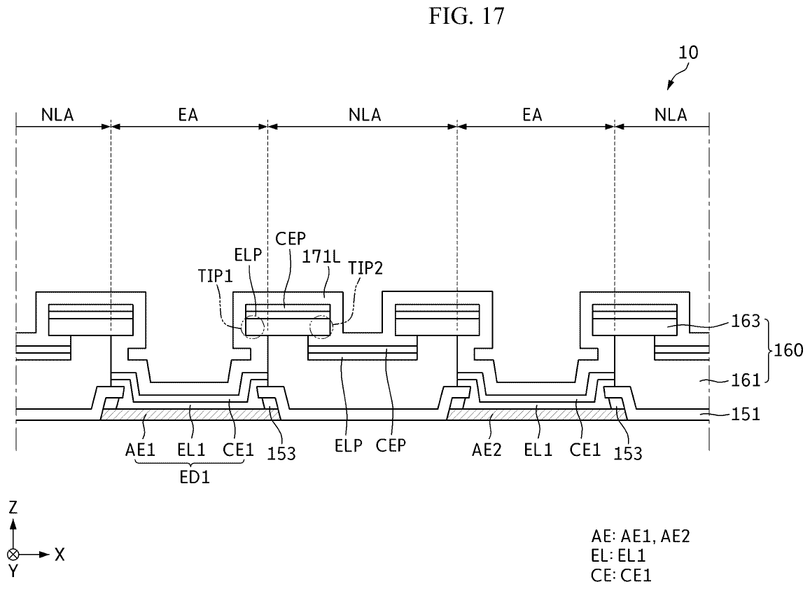

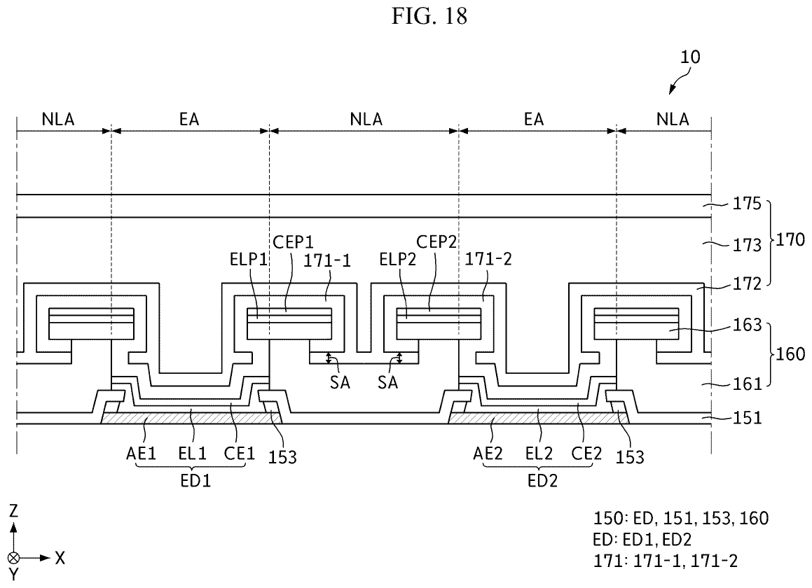

FIGS. 7 to 18 are schematic cross-sectional views illustrating a method of fabricating the display element layer and the thin film encapsulation layer in FIG. 4. Hereinafter, a fabricating process of the display device 10 will be described in relation to the formation order of each layer.

In the descriptions of the method herein, the operations may be performed in a different order than the order shown and/or described, or the operations may be performed in different orders or at different times. Certain operations may also be left out of the method, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 7, the method may include forming an anode electrode AE on the thin film transistor layer 130, and forming a sacrificial layer SFL on the anode electrode AE. Although not illustrated in FIG. 7, a structure of the thin film transistor layer 130 is the same as that described herein with reference to FIG. 4. A repeated detailed description thereof is omitted. A plurality of anode electrodes AE and sacrificial layers SFL may be positioned in portions overlapping the emission areas EA, and the plurality of anode electrodes AE and the sacrificial layers SFL may be disposed to be spaced apart from each other.

The sacrificial layer SFL according to an embodiment may assist in preventing the anode electrode AE and the pixel defining layer 151 from coming into contact with each other. In some aspects, the sacrificial layer SFL may protect the anode electrode AE in a subsequent etching process. The sacrificial layer SFL may include an oxide semiconductor. As an example, the sacrificial layer SFL may include at least one of indium gallium zinc oxide (IGZO), zinc tin oxide (ZTO), and indium tin oxide (IZO).

Subsequently, the method may include forming a pixel defining material layer 151L and a bank material layer 160L on the plurality of anode electrodes AE and the sacrificial layers SFL. The pixel defining material layer 151L may entirely cover the sacrificial layers SFL and the thin film transistor layer 130, and the bank material layer 160L may entirely cover the pixel defining material layer 151L. The bank material layer 160L may include a first bank material layer 161L and a second bank material layer 163L.

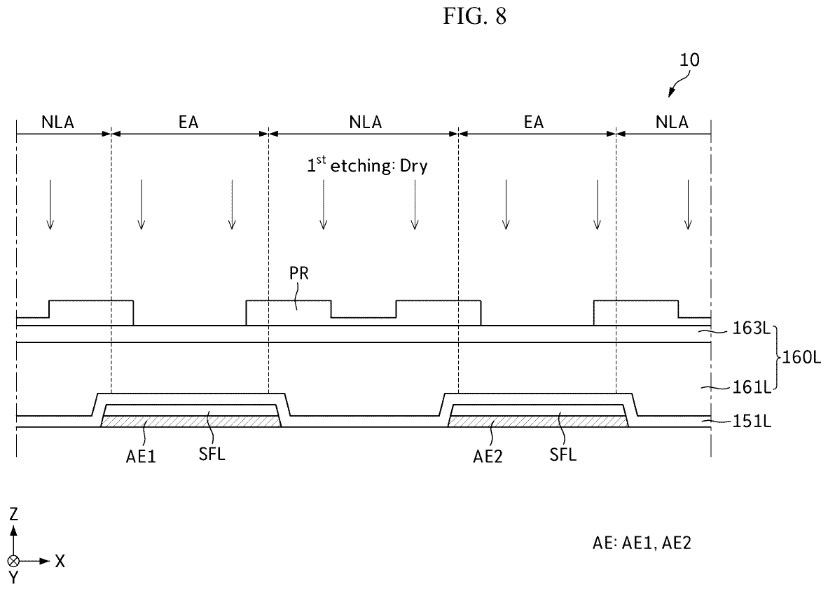

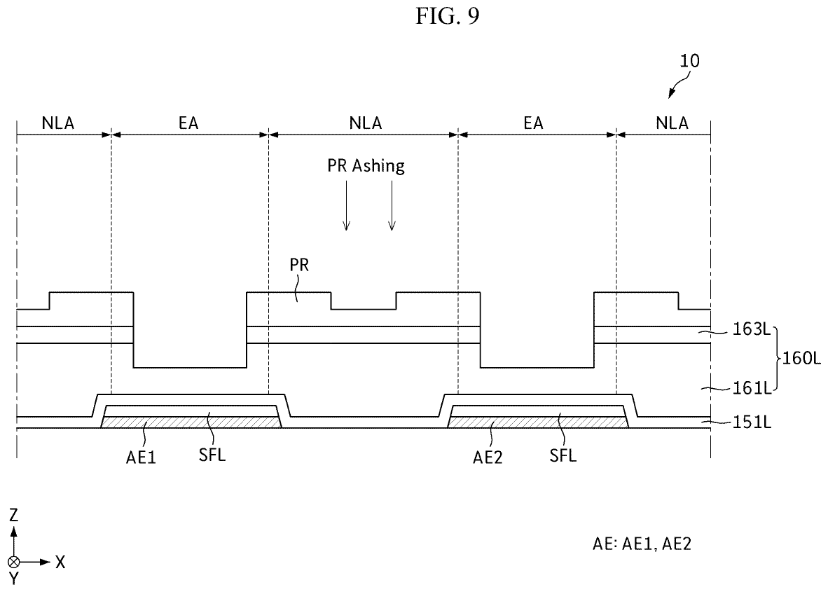

Next, referring to FIGS. 8 and 9, the method may include forming photoresists PR on the second bank material layer 163L, and performing a first etching process (1^{st} etching) using the photoresists PR as a mask. As an example, the method may include performing a dry etching process as the first etching process (1^{st} etching).

In the present process, the method may include forming the photoresists PR in the form of a halftone mask. A plurality of photoresists PR may be spaced apart from each other on the second bank material layer 163L while exposing portions overlapping the respective anode electrodes AE. In the present process, the method may include isotropically etching the first bank material layer 161L and the second bank material layer 163L including different metal materials.

Subsequently, the method may include performing a photoresist ashing process (PR Ashing). In the present process, the method may include removing a portion of the photoresist PR formed at a relatively low height.

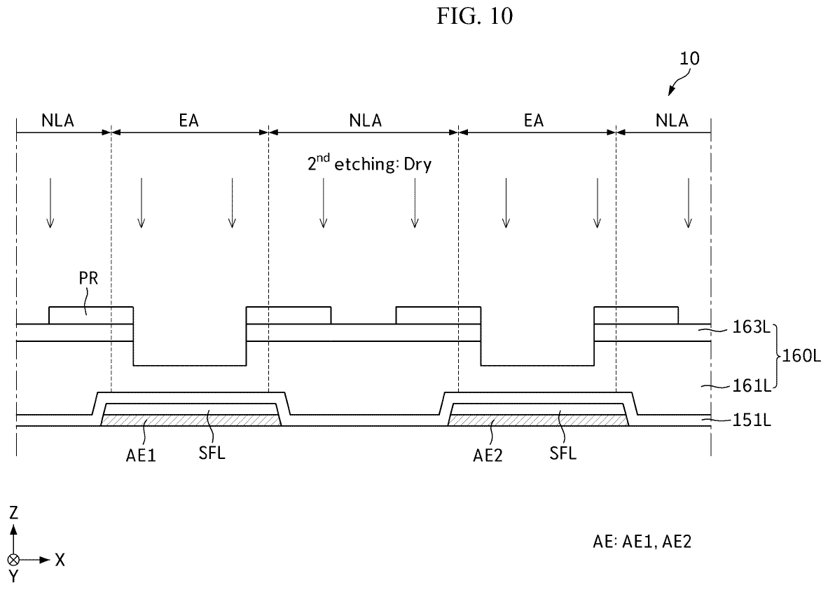

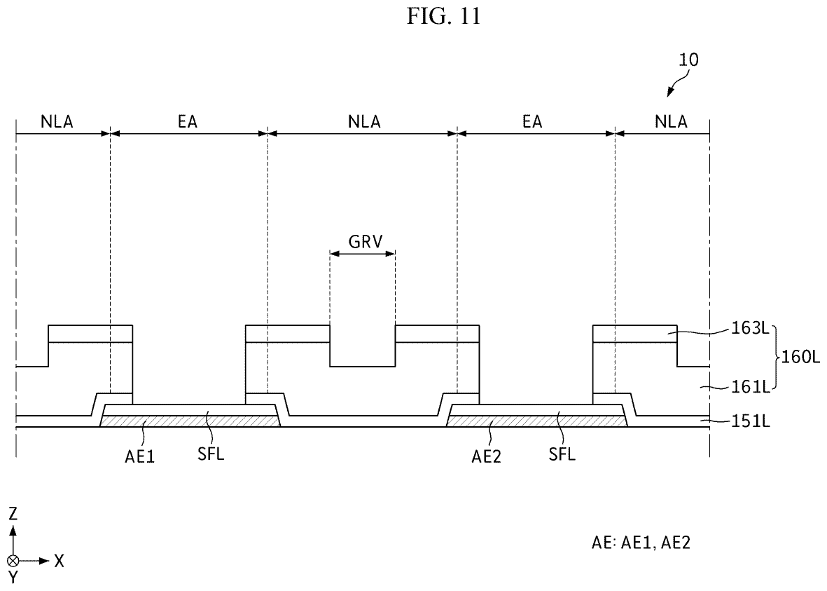

Next, referring to FIGS. 10 and 11, the method may include performing a second etching process (2^{nd} etching) using the photoresists PR remaining in the photoresist ashing process (PR Ashing) as a mask. As an example, the method may include performing a dry etching process as the second etching process (2^{nd} etching).

In the present process, the method may include removing portions of the bank material layer 160L and portions of the pixel defining material layer 151L. The removal of the portions of the bank material layer 160L and the portions of the pixel defining material layer 151L may expose the sacrificial layer SFL positioned in a portion overlapping the emission area EA. The removal of the portions of the bank material layer 160L and the portions of the pixel defining material layer 151L may form the groove GRV in a portion of the bank material layer 160L positioned in a portion overlapping the non-emission area NLA.

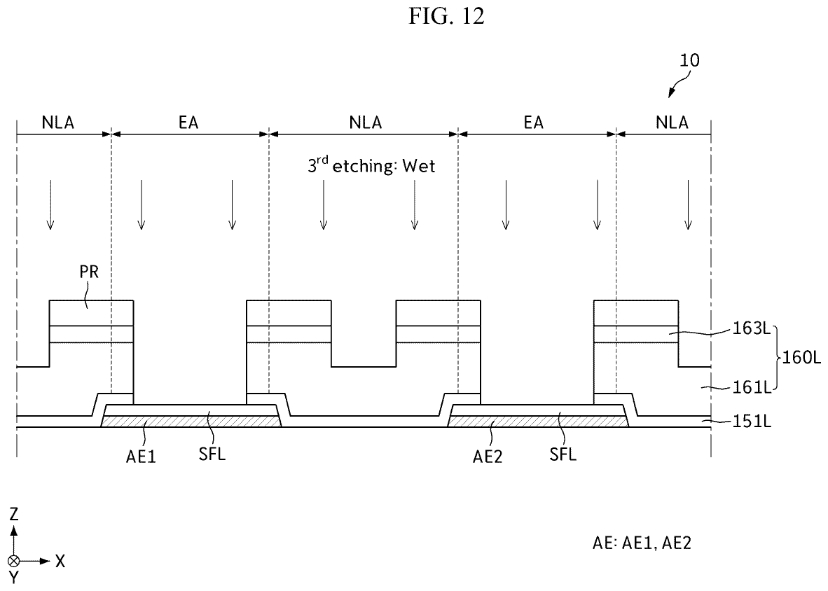

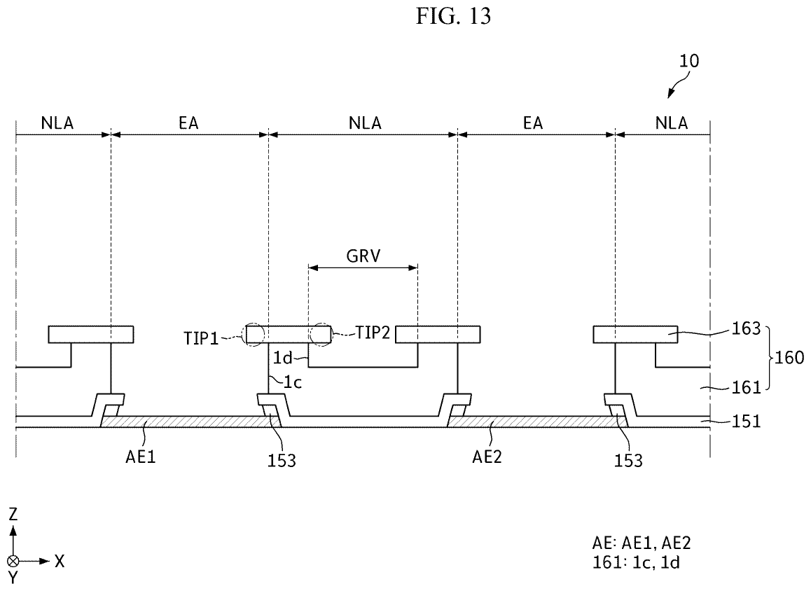

Next, referring to FIGS. 12 and 13, the method may include performing a third etching process (3^{rd} etching) using the photoresists PR as a mask. As an example, the method may include performing a wet etching process as the third etching process (3^{rd} etching). In the present process, the method may include forming the bank material layer 160L, the pixel defining material layer 151L, and the sacrificial layers SFL in the form of the first bank layer 161, the second bank layer 163, the pixel defining layer 151, and the residual patterns 153 illustrated in FIG. 4, and the method may include exposing the anode electrodes AE.

In the present process, the method may include anisotropically etching the first bank material layer 161L and the second bank material layer 163L including different materials. Specifically, the first bank material layer 161L may have a higher etch rate than the second bank material layer 163L. Accordingly, for example, the second bank layer 163 may include the first tip TIP1 protruding toward the emission area EA more than the first side surface 1c of the first bank layer 161 and the second tip TIP2 protruding toward the groove GRV more than the second side surface 1d of the first bank layer 161.

In the present process, the sacrificial layers SFL may not be completely removed, and the sacrificial layers SFL may remain as partial residual patterns 153 in spaces between the pixel defining layer 151 and the anode electrodes AE. The residual pattern 153 may be positioned in a portion overlapping the first tip TIP1 of the second bank layer 163.

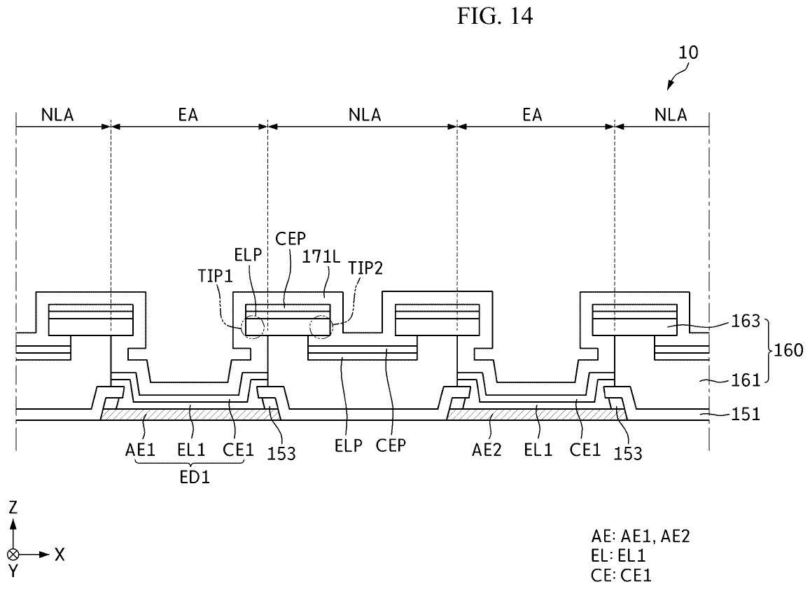

Next, referring to FIG. 14, the method may include forming the first light emitting layer EL1 and the first cathode electrode CE1 on the first anode electrode AE1. In the present process, the first light emitting element ED1 may be formed.

The light emitting layer EL according to an embodiment may be formed through a thermal evaporation process. The method may include performing the thermal evaporation process of forming the light emitting layer EL at an inclined angle of 45° to 50° with respect to an upper surface of the anode electrode AE. Accordingly, for example, the light emitting layer EL may be formed such that the light emitting layer EL fills a space between the anode electrode AE and the pixel defining layer 151 spaced apart from each other, and such that the light emitting layer EL is formed on a side surface of the first bank layer 161 hidden by the first tip TIP1 of the second bank layer 163.

The method may include forming the cathode electrode CE according to an embodiment through a thermal evaporation process. The method may include performing the thermal evaporation process of forming the cathode electrode CE at an inclined angle of 30° to 40° with respect to an upper surface of each anode electrode AE. That is, the method may include performing the thermal evaporation process of forming the cathode electrode CE in an inclined direction closer to the upper surface of the anode electrode AE than the thermal evaporation process of forming the light emitting layer EL. Accordingly, for example, the cathode electrode CE according to an embodiment may be formed on the side surface of the first bank layer 161 hidden by the first tip TIP1 of the second bank layer 163, and may entirely cover the light emitting layer EL.

In the present process, materials forming the first light emitting layer EL1 and the first cathode electrode CE1 may be formed not only on the first anode electrode AE1, but also on the second anode electrode AE2, the first bank layer 161, and the second bank layer 163. In the present process, the material forming the first light emitting layer EL1 and the material forming the first cathode electrode CE1, which are positioned on the second bank layer 163, may become the organic pattern ELP and the electrode pattern CEP illustrated in FIG. 4.

Since the second bank layer 163 according to an embodiment includes the first tip TIP1 protruding toward the emission area EA, the first light emitting layer EL1 and the first cathode electrode CE1 may be spaced apart from the organic pattern ELP and the electrode pattern CEP.

In the present process, the method may include forming the organic pattern ELP and the electrode pattern CEP on the first bank layer 161 in a portion overlapping the non-emission area NLA. However, the method may include removing, by a subsequent etching process, the organic pattern ELP and the electrode pattern CEP formed on the first bank layer 161.

Next, the method may include forming a first encapsulation material layer 171L on the first cathode electrode CE1 and the electrode pattern CEP. The method may include forming the first encapsulation material layer 171L through a chemical vapor deposition (CVD) process, and the method may include forming the first encapsulation material layer 171L as a uniform film regardless of a step of an underlying structure. As an example, the first encapsulation material layer 171L may cover the first tip TIP1 and the second tip TIP2, an undercut formed by the first tip TIP1 and the first bank layer 161, and an undercut formed by the second tip TIP2 and the first bank layer 161.

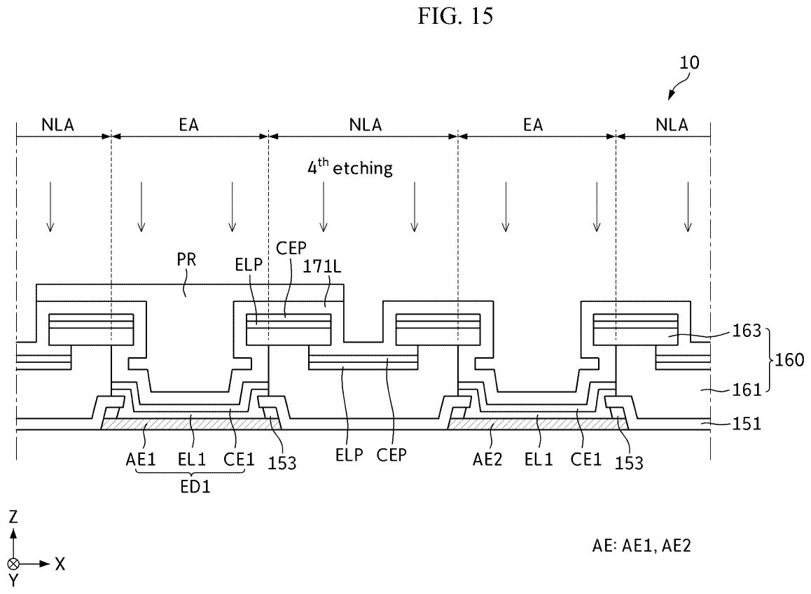

Subsequently, referring to FIGS. 15 to 18, the method may include forming a photoresist PR on the first anode electrode AE1 and the second bank layer 163 positioned around the first anode electrode AE1, and the method may include performing a fourth etching process (4^{th} etching) using the photoresist PR as a mask. As an example, as the fourth etching process (4^{th} etching), the method may include alternately performing wet etching processes and dry etching processes.

In the present process, the method may include removing the first light emitting layer EL1, the first cathode electrode CE1, the organic pattern ELP, the electrode pattern CEP, and the first encapsulation material layer 171L in a portion where the photoresist PR is not formed. In the present process, the organic pattern ELP, the electrode pattern CEP, and the first encapsulation material layer 171L may be formed in the form of the first organic pattern ELP1, the first electrode pattern CEP1, and the first inorganic layer 171-1 illustrated in FIG. 4.

In the present process, the method may include removing the organic pattern ELP and electrode pattern CEP positioned on the first bank layer 161, and the removal may form the space SA in the third direction (Z-axis direction) between the first inorganic layer 171-1 and the first bank layer 161 in a portion overlapping the groove GRV. In other words, in a portion overlapping the second tip TIP2, the first bank layer 161 and the first inorganic layer 171-1 may be spaced apart from each other in the third direction (Z-axis direction) with the space SA interposed the first bank layer 161 and the first inorganic layer 171-1.

In the present process, the first inorganic layer 171-1 may entirely surround the first tip TIP1 and the second tip TIP2, and may entirely surround the first organic pattern ELP1 and the first electrode pattern CEP1.

Next, the method may include forming the second light emitting layer EL2, the second cathode electrode CE2, the second organic pattern ELP2, the second electrode pattern CEP2, and the second inorganic layer 171-2 on the second anode electrode AE2 by performing the processes described herein. In the present process, the light emitting element ED, the pixel defining layer 151, residual pattern 153, and the bank structure 160 included in the display element layer 150 may be formed. The first inorganic layer 171-1 and the second inorganic layer 171-2 may be spaced apart from each other in the first direction (X-axis direction) with the groove GRV interposed between the first inorganic layer 171-1 and the second inorganic layer 171-2. An overlapping description is omitted.

Next, the method may include forming the thin film encapsulation layer 170 by forming the second encapsulation layer 172, the third encapsulation layer 173, and the fourth encapsulation layer 175 on the first encapsulation layer 171.

In the present process, the method may include forming the second encapsulation layer 172 by a chemical vapor deposition process, and the second encapsulation layer 172 may be formed at the same thickness along a profile formed by the first encapsulation layer 171 positioned below the second encapsulation layer 172. The method may include filling the space SA formed between the first encapsulation layer 171 and the first bank layer 161 with the second encapsulation layer 172. The method may include forming the third encapsulation layer 173 by an inkjet method, and the method may include planarizing a profile formed by the second encapsulation layer 172.

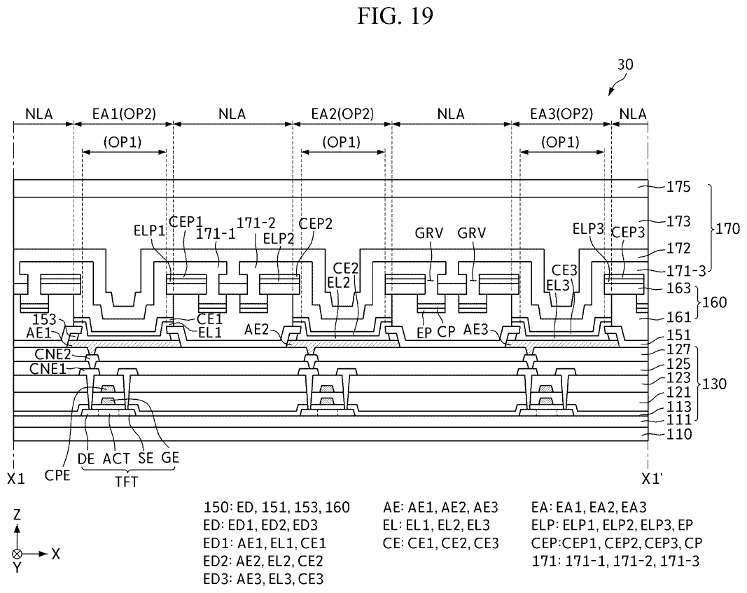

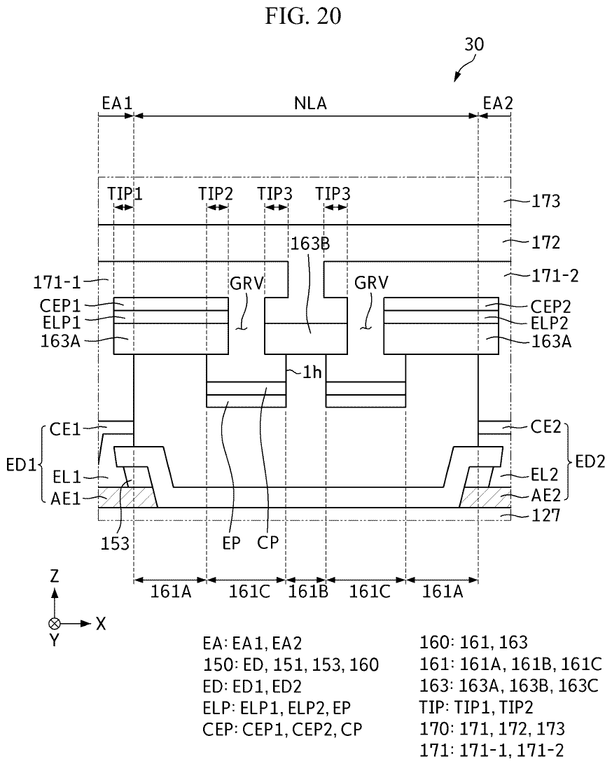

FIG. 19 is a schematic cross-sectional view of a display area taken along line X1-X1′ of FIG. 3 according to another embodiment. FIG. 20 is an enlarged cross-sectional view of a display element layer and a thin film encapsulation layer overlapping a non-emission area LNA positioned between a first emission area and a second emission area in FIG. 19.

Referring to FIGS. 19 and 20, a bank structure 160 included in a display device 30 may have a different structure from the bank structure 160 of the display device 10. Hereinafter, a description of a common structure between the display device 10 and the display device 30 is omitted, and differences between the display device 10 and the display device 30 will be described later.

The bank structure 160 included in the display device 30 may include a plurality of grooves GRV formed in a portion overlapping the non-emission area NLA. Embodiments of the present disclosure may include forming the groove GRV by etching a portion of the bank structure 160 in a fabricating process of the display device 30.

The groove GRV included in the display device 30 may have a bent shape according to different etch rates of the first bank layer 161 and the second bank layer 163. That is, a width of the groove GRV in the first direction (X-axis direction) may be greater between a plurality of first bank layers 161 than between a plurality of second bank layers 163.

In some embodiments, the first bank layer 161 included in the display device 30 may include first portions 161A, a second portion 161B, and third portions 161C in a portion overlapping the non-emission area NLA. The first portions 161A, the second portion 161B, and the third portions 161C may be integrally formed.

In some embodiments, each of the first portions 161A may be a portion positioned in a direction toward the emission area EA and in contact with the light emitting element ED. The second portion 161B may be a portion positioned between a plurality of first portions 161A and not in contact with the light emitting element ED. The third portion 161C may be a portion positioned between the first portion 161A and the second portion 161B and overlapping the groove GRV of the bank structure 160. The first portion 161A and the second portion 161B of the first bank layer 161 included in the display device 30 may be spaced apart from each other in the first direction (X-axis direction) with the groove GRV interposed between the first portion 161A and the second portion 161B.

In some embodiments, organic residual patterns EP may be positioned on the third portions 161C of the first bank layer 161. The organic residual patterns EP may include the same material as the light emitting layer EL, the first organic pattern ELP1, and the second organic pattern ELP2. The second bank layer 163 includes second tips TIP2 and third tips TIP3, and accordingly, for example, a material forming the light emitting layer EL is spaced apart from the first organic patterns ELP1, the second organic pattern ELP2, and the third organic pattern ELP3, such that the organic residual patterns EP may be formed.

Electrode residual patterns CP may be positioned on the organic residual patterns EP included in the display device 30. The electrode residual patterns CP may be positioned in portions overlapping the third portions 161C of the first bank layer 161. The first electrode pattern CEP1, the second electrode pattern CEP2, the third electrode pattern CEP3, and the electrode residual pattern CP may all include the same material. The second bank layer 163 includes the second tips TIP2 and the third tips TIP3, and accordingly, for example, a material forming the cathode electrode CE is spaced apart from the first electrode pattern CEP1, the second electrode pattern CEP2, and the third electrode pattern CEP3, such that the electrode residual patterns CP may be formed.

In some embodiments, the second bank layer 163 included in the display device 30 may include first sub-portions 163A and a second sub-portion 163B. The first sub-portions 163A may be portions positioned on the first portions 161A of the first bank layer 161 and in contact with the first portions 161A. In some aspects, the second sub-portion 163B may be a portion positioned on the second portion 161B of the first bank layer 161 and in contact with the second portion 161B. The first sub-portion 163A and the second sub-portion 163B may be integrally formed in the fabricating process of the display device 30, and based on the formation of the groove GRV, the first sub-portion 163A and the second sub-portion 163B may be spaced apart from each other in the first direction (X-axis direction) with the groove GRV interposed between the first sub-portion 163A and the second sub-portion 163B. The first sub-portion 163A and the second sub-portion 163B of the second bank layer 163 may be electrically connected to each other by the first bank layer 161.

In some embodiments, the second sub-portion 163B of the second bank layer 163 may have the third tip TIP3 protruding in the first direction (X-axis direction) more than a side surface 1h included in the second portion 161B of the first bank layer 161. The second tip TIP2 and the third tip TIP3 may be positioned in a portion overlapping the groove GR V of the bank structure 160. As described herein, the organic residual patterns EP and the electrode residual patterns CP positioned on the third portions 161C of the first bank layer 161 may be spaced apart from the first organic pattern ELP1, the second organic pattern ELP2, the first electrode pattern CEP1, and the second electrode pattern CEP2 by the second tips TIP2 and the third tips TIP3 included in the second bank layer 163.

In some embodiments, the organic pattern ELP and the electrode pattern CEP included in the display device 30 may not be positioned on the second sub-portion 163B. In the fabricating process of the display device 30, the fabricating may include forming the organic pattern ELP and the electrode pattern CEP on the second sub-portion 163B and then removing the organic pattern ELP and the electrode pattern CEP (or portions thereof) by a subsequent etching process. Accordingly, for example, an upper surface of the second sub-portion 163B may be exposed, and may be in contact with the second encapsulation layer 172.

The first encapsulation layer 171 included in the display device 30 may be positioned on the cathode electrode CE and the electrode pattern CEP, and may be in contact with the cathode electrode CE and the electrode pattern CEP. The first encapsulation layer 171 included in the display device 30 may entirely cover the first tip TIP1 and the second tip TIP2, and may partially cover the third tip TIP3. The first encapsulation layer 171 included in the display device 30 may entirely fill a portion overlapping the groove GRV of the bank structure 160.

In other words, in the display device 30, the bank structure 160 may include the plurality of grooves GRV in the portion overlapping the non-emission area NLA, and may include the first tip TIP1, the second tip TIP2, and the third tip TIP3.

In the display device 30, the bank structure 160 includes the first tip TIP1, and accordingly, for example, the light emitting element ED positioned in a portion overlapping each emission area EA may be formed without using a separate fine metal mask. Accordingly, for example, embodiments of the present disclosure provide a high-resolution display device having a high degree of integration of pixels.

In some aspects, the first encapsulation layer 171 included in the display device 30 may cover the tips TIP of the bank structure 160, and may entirely cover the organic pattern ELP and the electrode pattern CEP. Accordingly, for example, the display device 30 may solve a reliability defect caused by permeation of oxygen and moisture in the fabricating process.

The invention should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising an emission area and a non-emission area;
a first light emitting element positioned on the emission area of the substrate;
a pixel defining layer positioned on the non-emission area of the substrate and defining a first opening;
a bank structure positioned on the pixel defining layer, defining a second opening, and comprising a groove; and
a first encapsulation layer positioned on the first light emitting element and the bank structure,
wherein:
the bank structure comprises:
a first bank layer comprising a first side surface facing the emission area and a second side surface opposing the first side surface; and
a second bank layer positioned on the first bank layer and comprising a first tip protruding toward the emission area more than the first side surface and a second tip protruding toward the groove more than the second side surface, and the first encapsulation layer entirely covers the first tip and the second tip.

2. The display device of claim 1, further comprising a second light emitting element spaced apart from the first light emitting element with the pixel defining layer and the bank structure interposed between the second light emitting element spaced apart and the first light emitting element,
wherein the first light emitting element and the second light emitting element are in contact with the first bank layer.

3. The display device of claim 2, wherein the first light emitting element and the second light emitting element are electrically connected to each other through the first bank layer.

4. The display device of claim 3, wherein:
the first bank layer comprises aluminum, and
the second bank layer comprises titanium.

5. The display device of claim 4, wherein in a plan view, the second opening entirely surrounds the first opening.

6. The display device of claim 2, wherein:
the first bank layer comprises:
a first portion in contact with the first light emitting element;
a second portion in contact with the second light emitting element; and
a third portion overlapping the groove,
the first portion, the second portion, and the third portion are integrally formed, and
the third portion is positioned between the first portion and the second portion.

7. The display device of claim 6, wherein the third portion is spaced apart from the first encapsulation layer with a space interposed between the third portion and the first encapsulation layer in a direction perpendicular to the substrate.

8. The display device of claim 7, further comprising a second encapsulation layer positioned on the first encapsulation layer,
wherein the third portion is in contact with the second encapsulation layer.

9. The display device of claim 6, wherein:
the second bank layer comprises a first sub-portion positioned on the first portion of the first bank layer and a second sub-portion positioned on the second portion of the first bank layer, and
the first sub-portion and the second sub-portion are spaced apart from each other in a direction parallel to the substrate.

10. The display device of claim 9, wherein:
the first encapsulation layer comprises a first inorganic layer entirely covering the first sub-portion and a second inorganic layer entirely covering the second sub-portion, and
the first inorganic layer and the second inorganic layer are spaced apart from each other in the direction parallel to the substrate.

11. The display device of claim 1, wherein:
the first light emitting element comprises an anode electrode, a light emitting layer, and a cathode electrode, and
the light emitting layer and the cathode electrode are in contact with the first side surface.

12. The display device of claim 11, further comprising:
an organic pattern positioned on the second bank layer, comprising a same material as the light emitting layer, and spaced apart from the light emitting layer; and
an electrode pattern positioned on the organic pattern, comprising a same material as the cathode electrode, and spaced apart from the cathode electrode,
wherein the organic pattern and the electrode pattern overlap the first tip and the second tip.

13. The display device of claim 12, wherein:
the organic pattern and the electrode pattern are positioned such that the organic pattern and the electrode pattern surround the first opening, and
the first encapsulation layer entirely covers the organic pattern and the electrode pattern.

14. The display device of claim 11, further comprising a residual pattern positioned between the anode electrode and the pixel defining layer in a direction perpendicular to the substrate,
wherein the residual pattern overlaps the first tip.

15. The display device of claim 14, wherein the residual pattern is in contact with the light emitting layer.

16. The display device of claim 1, wherein:
the first bank layer comprises:
a first portion in contact with the first light emitting element;
a second portion spaced apart from the first portion and not in contact with the first light emitting element; and
a third portion overlapping the groove,
the first portion, the second portion, and the third portion are integrally formed, and
the third portion is positioned between the first portion and the second portion.

17. The display device of claim 16, wherein:
the second bank layer comprises a first sub-portion positioned on the first portion and a second sub-portion positioned on the second portion, and
the first sub-portion and the second sub-portion are spaced apart from each other in a direction parallel to the substrate.

18. The display device of claim 17, further comprising:
an organic pattern and an electrode pattern positioned on the first sub-portion of the second bank layer; and
an organic residual pattern and an electrode residual pattern positioned on the third portion of the first bank layer,
wherein:
the organic pattern and the organic residual pattern are spaced apart from each other, and
the electrode pattern and the electrode residual pattern are spaced apart from each other.

19. The display device of claim 18, wherein the first encapsulation layer entirely covers the electrode pattern and the electrode residual pattern.

20. A method of fabricating a display device, comprising:
forming a substrate comprising an emission area and a non-emission area, forming an anode electrode and a sacrificial layer on the emission area of the substrate, and forming a pixel defining layer and a bank structure on the sacrificial layer, the bank structure comprising a first bank layer and a second bank layer;
exposing the anode electrode by removing the pixel defining layer and the bank structure positioned in a portion overlapping the emission area, and forming a groove by removing a portion of the bank structure positioned in a portion overlapping the non-emission area;
forming the second bank layer comprising a first tip and a second tip by removing portions of the bank structure, the first tip protruding toward the emission area more than a first side surface of the first bank layer and the second tip protruding toward the groove more than a second side surface of the first bank layer; and
forming a light emitting element by forming a light emitting layer and a cathode electrode on the anode electrode and the bank structure, and forming an encapsulation layer entirely covering the first tip and the second tip.

21. An electronic device, comprising:
a display device comprising: a substrate comprising an emission area and a non-emission area;
a first light emitting element positioned on the emission area of the substrate;
a pixel defining layer positioned on the non-emission area of the substrate and defining a first opening;
a bank structure positioned on the pixel defining layer, defining a second opening, and comprising a groove; and
a first encapsulation layer positioned on the first light emitting element and the bank structure,
wherein:
the bank structure comprises:
a first bank layer comprising a first side surface facing the emission area and a second side surface opposing the first side surface; and
a second bank layer positioned on the first bank layer and comprising a first tip protruding toward the emission area more than the first side surface and a second tip protruding toward the groove more than the second side surface, and the first encapsulation layer entirely covers the first tip and the second tip.
